(19) United States
(12) Patent Application Publication
(10) Pub. No.: US 2001/0010460 A1
(43) Pub. Date: Aug. 2, 2001

(54) Method for locating energized electric conductor

(76) Inventors: Lawrence F. Miller, Los Gatos, CA (US); Charles E. Heger, Saratoga, CA (US)

Correspondence Address: Norman R. Klivans, Skjerven Morrill MacPherson LLP, 25 Metro Drive, Suite 700, San Jose, CA, 95110, US

(21) Appl. No.: 09/832,244

(22) Filed: Apr. 9, 2001

Related U.S. Application Data
(62) Division of application No. 09/365,977, filed on Aug. 2, 1999.

(51) Int. Cl. G01R 19/00; G01V 3/10

(52) U.S. Cl. 324/67; 324/326

(57) ABSTRACT

A single-sensor measurement system for detection and location of an AC signal emanating from a concealed energized electric conductor. A calibration routine of a measurement process carried out by the instrument first determines the background signal level of the AC signal at an initial position of the instrument. A second AC signal level is measured at a second location. The second signal level is compared with the background signal level. A signal indicating the presence of the energized electric conductor is generated by the instrument when the comparison result is greater than or equal to a predetermined value. The instrument initially positioned directly over a concealed energized electric conductor is automatically re-calibrated when a decrease in the AC signal level of a predetermined amount is detected. The electric field sensor is directly printed on the inside bottom panel of the instrument case and over the raised portions formed on the inside bottom panel. Electrical contact is made between the electric field sensor and the associated circuitry on a PCB in the case when the instrument is assembled.

### FIELD OF THE INVENTION

This invention relates to electronic detection devices and more particularly to a device and method for locating a conductor having an alternating electric field, for instance, a wire present inside a wall of a structure or buried in the ground.

### BACKGROUND OF THE INVENTION

There are a large number of techniques and devices for determining the location of an electric conductor, in the context of the electric conductor being located in a wall or floor of a structure, in the ground or under water. Many of these techniques detect the magnetic field or the electric field emanating from the energized electric conductor. The magnetic field detectors utilize inductive coils for detection which requires a current flow in the conductor, and typically utilize a transmitter unit plugged into the wall socket and a hand-held receiver unit for detection. The electric field detectors directly detect the electric field of an active conductor without a separate transmitter and are simpler and less expensive than the magnetic field detectors. However, electric field detectors have several drawbacks. For example, the material of the wall, e.g. sheetrock, wood, etc., is a dielectric and affects the electric field patterns. Specifically, the wall material spreads the electric field over a large area. Another drawback is that in order to determine the location of a conductor behind, e.g., a wall, the electric field detector must be able to distinguish small changes in electric field against a large electric field background which can vary widely depending on the depth of the conductor and the type of wall material. Thus, the electric field detector must be able to handle a large dynamic range of electric field background. Furthermore, the body of the user affects the electric field measurement as well because the capacitive coupling between the user and the measuring instrument and between the user and the wall complete the electric field measurement circuit.

Electric field detectors detect hidden electric conductors using either a single electric field sensor (electrode) or multiple electric field sensors. Single-electrode electric field detectors determine only an absolute amplitude of AC (alternating current) electric field signal for a conductor and do a poor job in locating the conductor's position. Multiple-electrode electric field detectors, on the other hand, eliminate many of the drawbacks mentioned above by utilizing differential measurements to measure the spatial changes between electric fields. However, multiple-electrode electric field detectors are generally associated with differential measurements and are more complicated and expensive than single-sensor electric field detectors.

Therefore, what is needed is a single-sensor electric field detector that is capable of accurately detecting and locating a concealed electric conductor and a related method.

A typical electric field sensor is made of a conductive plate that is an integral part of a printed circuit board (PCB). However, such approach has several disadvantages identified by the present inventors. For example, considerable board space is required to implement the sensor directly on the PCB, thereby increasing unit size and cost. In addition, because the PCB is mounted above the bottom surface of the plastic case that typically encloses the PCB, there is an air gap between the electric field sensor and the sensor case. The air gap undesirably creates a series capacitance between the sensor and the sensor case, making the sensor less sensitive to the AC signal being detected.

Therefore, what is also needed is a sensor device that eliminates the air gap between a sensor and the associated case.

### SUMMARY

A single-sensor measurement system (hereinafter the “instrument”) including circuitry and carrying out a measurement process for low cost detection and location of an AC signal emanating from a concealed energized electric conductor is provided. A calibration routine of the measurement process first determines the background signal level of the AC signal at an initial position of the instrument relative to the conductor. A second AC signal level is measured at a second location. The process then compares the second signal level with the background signal level to obtain a result. A signal indicating the presence of the energized electric conductor is generated when the comparison result is greater than or equal to a predetermined value. The predetermined value is a fixed percentage increase greater than the background level. In one embodiment, an instrument positioned directly over a concealed conductor is automatically re-calibrated when a decrease in the AC signal level of a predetermined amount is detected.

In one embodiment, a programmable gain amplifier amplifies an AC signal detected by an electric field sensor. An amplitude comparison element measures the amplified AC signal. A digital output signal is generated by the amplitude comparison element and used by a microprocessor to control the amplitude comparison element and the programmable gain amplifier.

In one embodiment, the electric field sensor is directly printed on the inside bottom panel of the instrument case and over mesas (raised portions) formed on the inside bottom panel. Electrical contact is made between the electric field sensor and the associated circuitry which is on a PCB inside the case when the instrument is assembled. The direct printing not only improves performance by eliminating the air gap between the sensor and the instrument case, it also decreases required board space and thus, the manufacturing cost.

In one embodiment, the programmable gain amplifier includes a fixed gain amplifier coupled to a switched resistor array. In one embodiment, the switched resistor array includes a plurality of resistors coupled in parallel, each resistor having a corresponding switch coupled in series. In an alternative embodiment, the switched resistor array includes a plurality of resistors coupled in series, each resistor having a corresponding switch coupled in parallel. The switches are controlled by a microprocessor. By using a switched resistor array, the gain characteristics of the programmable gain amplifier can be modified by modifying the input load resistance of a fixed gain amplifier rather than changing the gain of a variable gain amplifier.

In one embodiment, the amplitude comparison element includes a peak-detection system which is implemented by coupling a flip-flop to a comparator, the flip-flop acting as a memory element to store a change in the comparator output. A microprocessor provides a reset signal to the flip-flop and a reference value signal whose amplitude is controlled by a pulse-width modulator. The comparator then compares the amplified input AC signal with the reference value. In another embodiment, a digital-to-analog converter (DAC) generates the reference value for the comparator. The DAC is coupled to and controlled by a microprocessor which is coupled to the comparator. A tracking process detects the peak amplitude of the amplified input AC signal.

In one embodiment, a visual display or an audible indicator is coupled to and controlled by the microprocessor. In one embodiment, a multifunctional LED alerts the presence of an electric conductor. In one embodiment, the LED blinks at a constant rate to warn the user that the instrument is near an AC signal source. In another embodiment, the LED blinks at varying rate to indicate whether the instrument is getting closer or getting further away from an AC signal source.

This invention will be more fully understood in light of the following detailed description taken together with the following drawings.

### BRIEF DESCRIPTION OF THE DRAWINGS

FIG. 1 shows a block diagram of an AC measurement system;

FIG. 2A shows a perspective view of a sensor electrode printed directly on an instrument case;

FIG. 2B shows a cross-sectional view of a sensor electrode printed directly on an instrument case;

FIG. 3 shows schematically a programmable gain amplifier using a parallel implementation of a switched resistor array;

FIG. 4 shows schematically a programmable gain amplifier using a series implementation of a switched resistor array;

FIG. 5 shows an embodiment of an amplitude comparison element;

FIG. 6 shows another embodiment of an amplitude comparison element; and

FIG. 7 shows a flowchart illustrating a method for detecting an energized electric conductor.

Use of the same reference numbers in different figures indicates similar or like elements.

### DETAILED DESCRIPTION

The following description is meant to be illustrative only and not limiting. Other embodiments of this invention will be apparent in view of the following description to those skilled in the art.

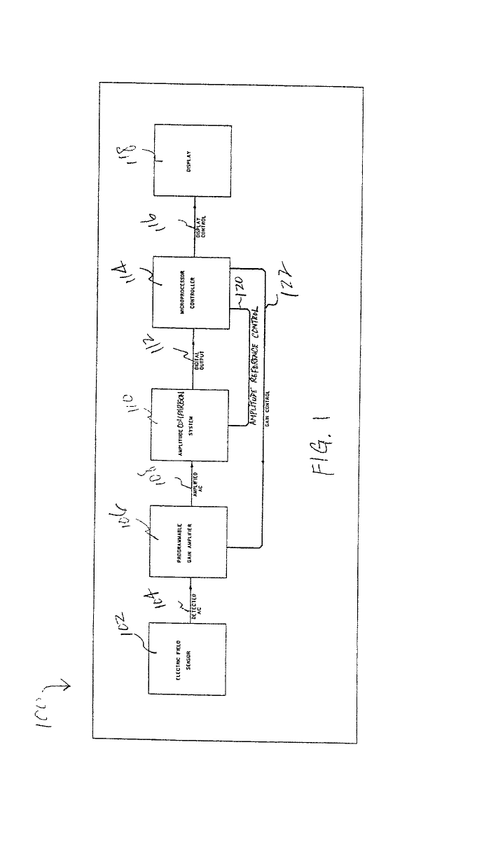

FIG. 1 illustrates a block diagram of an AC measurement system 100 which includes an electric field sensor 102 for detecting an AC signal emanating from a concealed energized electric conductor. The resulting AC signal on line 104 indicating detection is amplified by a programmable gain amplifier 106. The amplified signal on line 108 is measured by an amplitude comparison element 110. A digital signal on line 112 indicates whether or not the signal exceeds the reference level set up the microprocessor 114 on the amplitude reference control line 120. Microprocessor 114 then uses the amplitude information to set the amplifier gain for programmable gain amplifier 106 over a gain control line 122 and controls the amplitude comparison element 110 over an amplitude reference control line 120. (“Microprocessor” here generally refers to a microprocessor, micro-controller, or equivalent controller device.) In one embodiment, amplitude reference control line 120 is a single line for a pulse width modulator. In another embodiment, amplitude reference control line 120 is a bus including several lines when amplitude reference control line 120 controls a digital to analog converter (DAC). Gain control line 122 is typically actually a bus. Microprocessor 114 controls programmable gain amplifier and amplitude comparison element 110 as discussed in detail below. In one embodiment, microprocessor 114 also controls a display 118 which displays the resulting information over a display control line 116. Display 118 may be e.g., audible, using a beeper, or visual, using LEDs or a liquid crystal display. Microprocessor is, for example, a Microchip PIC 16C54 programmed to carry out the functionality disclosed herein; such programming is well within the skill of one of ordinary skill in the art.

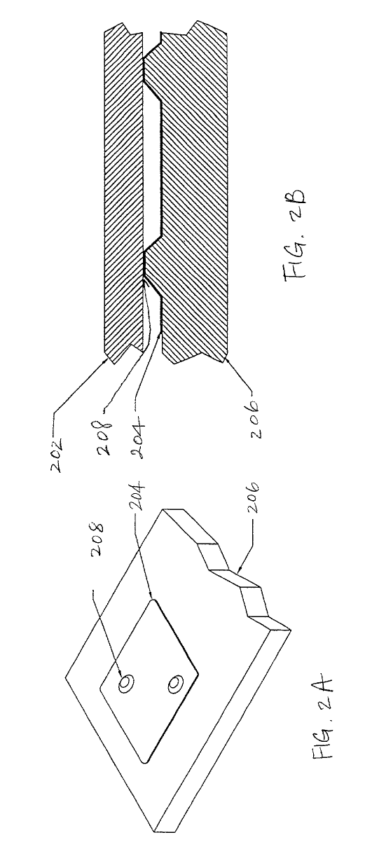

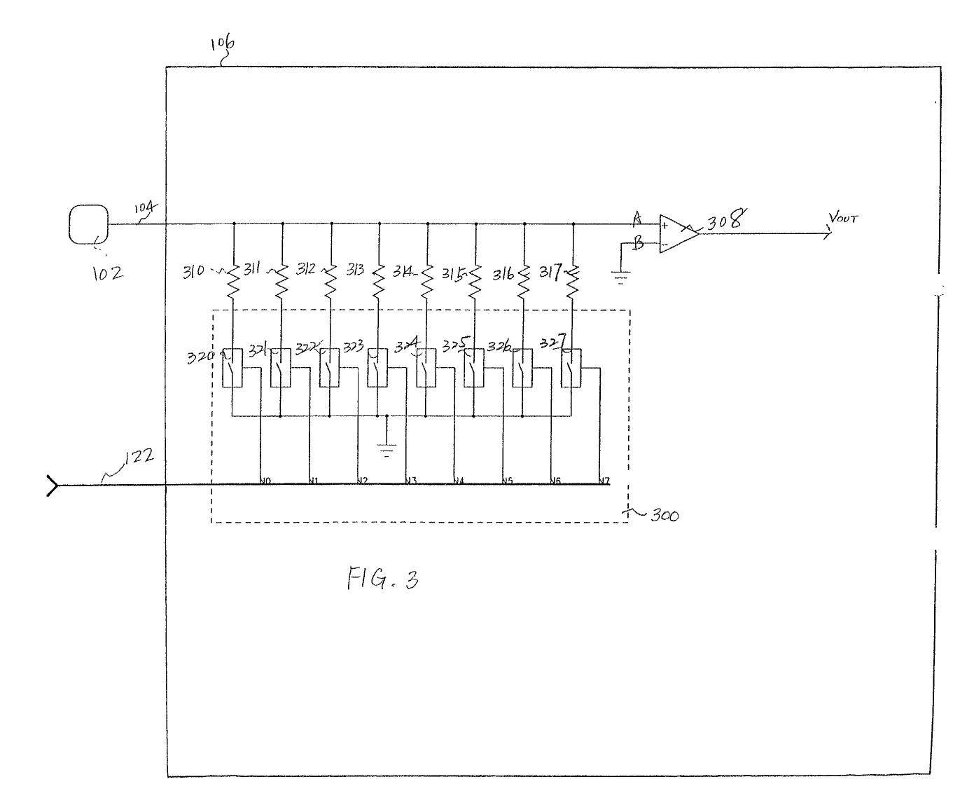

FIGS. 2A and 2B show a perspective view and a cross-sectional view, respectively, of a sensor electrode printed directly on an instrument case. Electric field sensor 102 has a sensor electrode 204 directly printed on an inside bottom panel of instrument case 206. Sensor electrode 204 is of a conventional conductive ink. Sensor electrode 204 interconnects to the associated circuitry on a printed circuit board 202 at the elevated contact areas (“mesas”) 208 formed on the inside bottom panel of instrument case 206. This interconnection takes place when the instrument is assembled. Sensor electrode 204 advantageously eliminates the air gap between the electrode and the instrument case in a conventional electric field sensing instrument, thereby increasing sensitivity.

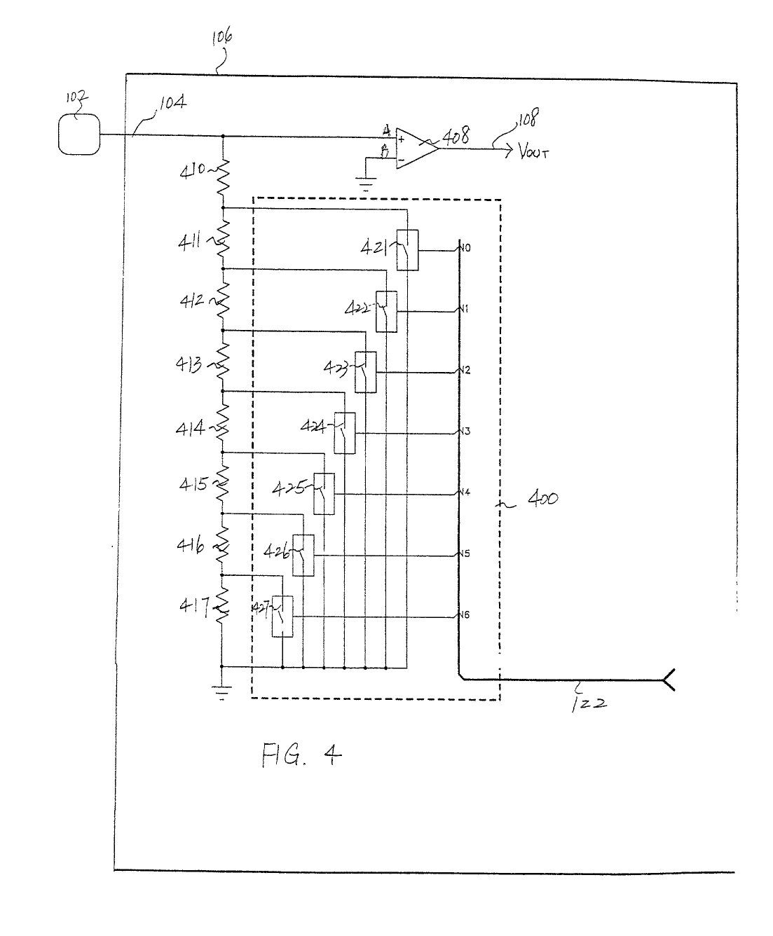

FIGS. 3 and 4 show schematically two embodiments of programmable gain amplifier 106. Programmable gain amplifier 106 provides the required dynamic range, typically about 20 to 30 dB, for measurement of background electric field. In one embodiment, a logarithmically programmed gain amplifier is used. A logarithmically programmed gain amplifier is desirable in AC detection because when the dynamic range is large, e.g., >20 dB, a logarithmically programmed gain amplifier provides equal step sizes regardless of signal amplitude. In addition, in AC signal detection, the sensor electrode is equivalent to a coupling capacitor of a few picofarads. At 60 Hertz (the typical AC frequency), a few picofarads is an extremely high impedance, typically, more than 100 Megohms. Because the input signal impedance is very high, the output signal of a fixed gain amplifier is proportional to the input load resistor. Therefore, in accordance with this invention, the programmable gain amplifier includes a single fixed gain amplifier and a switched resistor array coupled to an input terminal of the fixed gain amplifier. Other types of amplifier such as a linear gain amplifier may be used. However, a linear gain amplifier requires additional steps to maintain the output signal level within a particular range.

FIG. 3 shows a programmable gain amplifier 106 using a parallel implementation of a switched resistor array. Capacitive field sensor 102 detects an AC signal and provides in response an AC signal current on line 104 which is coupled to a resistor array having resistors 310 through 317 coupled in parallel. The resistor array is also coupled to an input terminal A of a fixed gain amplifier 308. Typical resistor values for resistors 310 through 317 are approximately 100 kilohms to approximately 3 megohms. Typical gain for fixed gain amplifier 308 is 300 (50 dB). AC signal current on line 104 is typically in the nano amp range.

Each resistor 310 through 317 is controlled by a corresponding switch 320 through 327 which is coupled in series with the resistor. In one embodiment, each switch 320 through 327 consists several transistors as part of an integrated circuit. In another embodiment, each switch 320 through 327 is a discrete transistor. In one embodiment, resistors 310 through 317 are part of the integrated circuit on a chip.

Each of the switches 320 through 327 in switch array 300 is in turn controlled by a gain control line 122 from microprocessor 114 through a digital decoder (not shown). Hence, depending on the position of each switch 320 through 327, the input load resistance of fixed gain amplifier 308 is modified, thereby changing the gain of programmable gain amplifier 106. For example, for an eight step amplifier (6 dB per step) with a 256 to 1 range (48 dB) of selectable gain, each resistor 310 through 317 has one half the resistance of the resistor in the previous stage. This is because the output signal (effectively, the gain) is proportional to resistance. Therefore, cutting a resistor in half cuts the output in half. It is noted that modifying the input load resistance to a fixed gain amplifier is simpler than modifying the gain of a variable gain amplifier which requires additional circuitry.

Programmable gain amplifier 106 in accordance with the present invention requires less board space than required by a variable gain amplifier because variable gain amplifiers are fairly complex, especially if gain variations are very large. In addition, circuitry for meeting the stability requirements is usually added when an analog system requires continuous feedback to maintain a constant output level, increasing the complexity and cost.

The same principle is applicable to a series implementation of a switched resistor array. FIG. 4 shows an alternative programmable gain amplifier using a series implementation of a switched resistor array having resistors 410 through 417 coupled in series. In this embodiment, capacitive field sensor 102 detects an input signal electric field strength 104 and is coupled to a resistor array and an input terminal A of a fixed gain amplifier 408. Typical resistor values for resistors 411 through 417 are approximately 100 kilohms to approximately 3 megohms. Typical gain for fixed gain amplifier 408 is 300 or 50 dB. Each resistor 411 through 417 is controlled by a corresponding switch 421 through 427 coupled in parallel with the resistor. Each switch 421 through 427 in switch array 400 is controlled by a gain control line 122 from microprocessor 114 through a digital decoder (not shown). Similar to the parallel implementation of programmable gain amplifier discussed above, the switch positions of switches 421 through 427 determine the input load resistance of fixed gain amplifier 408 which in turn determine the gain characteristic of programmable amplifier 106. The structures shown in FIGS. 3 and 4 can be used in a custom integrated circuit to provide excellent accuracy with minimum use of area, hence low cost.

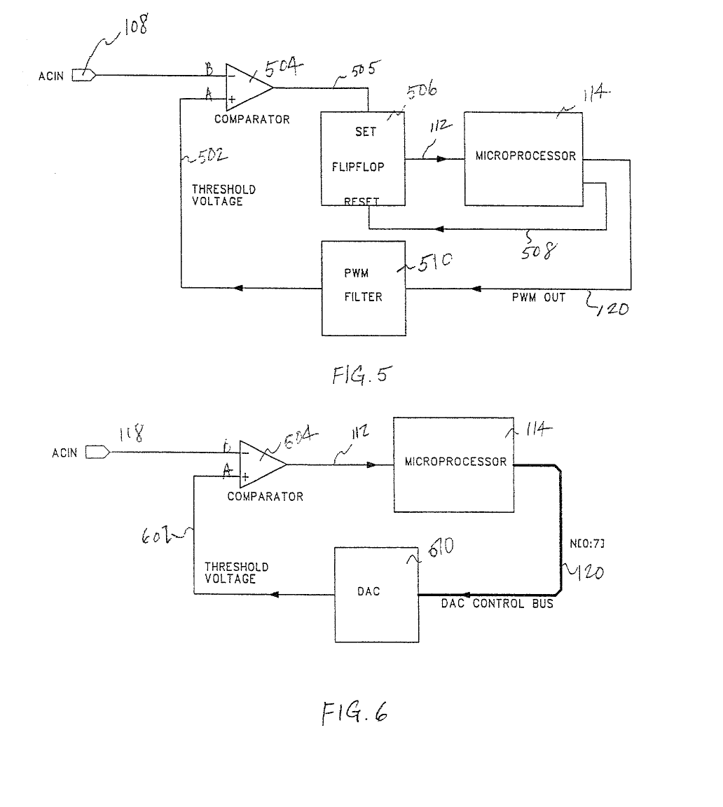

FIG. 5 illustrates schematically an embodiment of the amplitude comparison element 110 of FIG. 1. An amplified AC signal (AC_{IN}) on line 108 is compared to a reference value (THRESHOLD VOLTAGE) on line 502 by a comparator 504. The reference value on line 502 is controlled by microprocessor 114 through a pulse-width modulator (PWM) 510. Microprocessor 114 generates a variable duty cycle pulse train signal (PWM OUT) on amplitude reference control line 120. The PWM filter 510 removes the AC component of the pulse train, leaving only a DC level, the threshold voltage 502. The filtered amplitude reference control signal on amplitude reference control line 120, i.e., the reference value on line 502, is then used for the comparison.

If the peak amplitude of the amplified AC signal on line 108 exceeds the reference value on line 502, comparator 504 changes the state of output signal on line 505 which sets a flip-flop 506. Flip-flop 506 is therefore used as a memory element to store the information that output signal on line 505 has changed state. Flip-flop 506 is reset by a reset signal on line 508 from microprocessor 114.

In one embodiment, flip-flop 506 is an “SR” flip-flop having a pair of input terminals SET and RESET. After a momentary RESET, the flip-flop output will be low unless a subsequent SET input is received. If a subsequent SET input is received, the flip-flop stores this information until another RESET is received. By utilizing flip-flop 506 as a storage element, a peak AC signal can be detected. Because the flip-flop performs the peak detection function, microprocessor 114 can perform other functions during the intervening time, the other functions being, e.g., automatically measuring parameters such as time intervals, rise and fall times and frequency.

PWM filter 510 is relatively slow and requires a waiting period when an input value, i.e., PWM OUT, from microprocessor 114 changes, to allow the DC voltage to settle to the new value. Hence, while a PWM provides high resolution, it may not be fast enough for some applications.

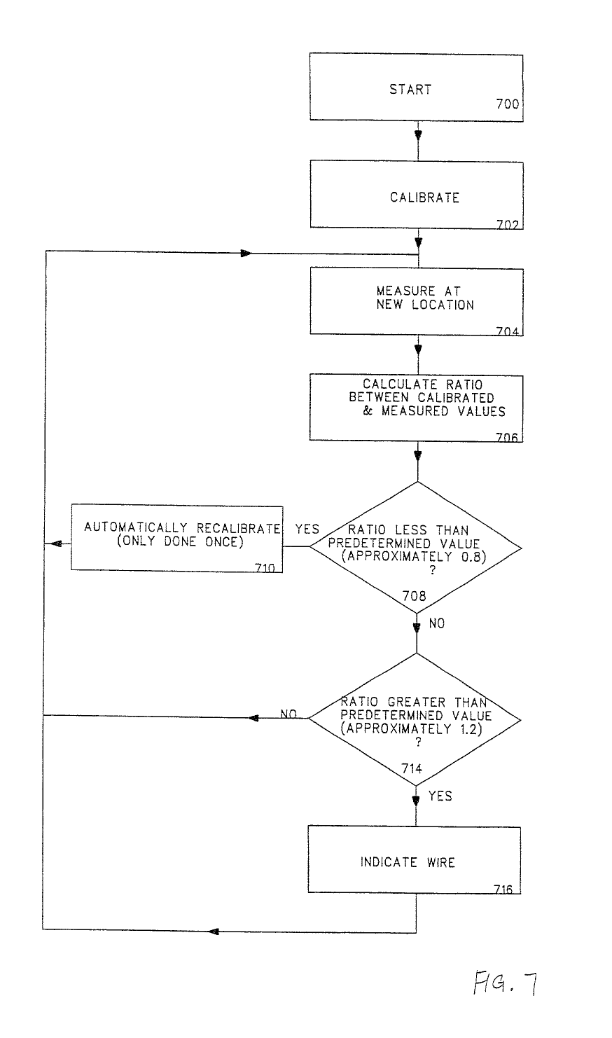

FIG. 6 shows an alternate embodiment of amplitude comparison element 110. In this embodiment, a digital to analog converter (DAC) 610 is used to increase the speed of the conversion operation. Microprocessor 114 varies the threshold rapidly enough to monitor the amplitude of amplified AC signal on line 108 as it varies (e.g., every 100 microseconds).

A tracking process rapidly measures the instantaneous amplitude of the amplified AC signal on line 108. The tracking process sets the value of DAC 610, then observes whether comparator 604 is high or low. If the output signal of comparator 604 is high, the value of the amplified AC input signal on line 108 is larger than the reference value (THRESHOLD VOLTAGE) on line 602 and the output signal for DAC 610 is increased 1 step. Similarly, if the output signal from comparator 604 is low, the value of the amplified AC input signal on line 108 is less than the reference value on line 602 and the output of DAC 610 is decreased one step. This process is repeated continuously, resulting in the output of DAC 610 continuously tracking the amplitude of the amplified AC input signal on line 108. By monitoring the output value of DAC 610, microprocessor 114 can observe the changes in direction which occurs as the signal passes through a maximum or minimum peak.

In the previous example, discussed in reference to FIG. 5, an entire period of the input frequency is required for one comparison. Hence, to measure the amplitude to a 1 bit resolution of an 8 bit system requires 8 periods or about 150 milliseconds. The tracking process, on the other hand, allows the same resolution in ½ cycle, since the instantaneous amplitude is determined and either the minimum or the maximum is determined as soon as the signal value achieves one or the other.

In one embodiment, the instrument is automatically recalibrated when the original calibration is performed at or near the point of maximum electric field, i.e., the instrument is very near or directly over the concealed conductor. Without recalibration, the instrument may fail to detect a hidden electric conductor since calibration occurred at the point of maximum signal, and no larger signal will be found. In one embodiment, as the instrument moves away from the concealed conductor, the electric field level decreases and when there is a sufficient decrease, the instrument recalibrates and alerts the user that the instrument is moving away from the concealed conductor by either a visual display or an audible indication. When the user returns the instrument to the original location where the first calibration occurred, the electric field would have increased sufficiently compared to the new calibration to trigger an indication indicating the presence of a concealed conductor.

“Homing in” on a electrical conductor is possible by successively recalibrating the unit. In one embodiment, the recalibration is triggered by the user pressing a reset button coupled to the microprocessor. In another embodiment, the recalibration is triggered by the user turning off and on the power to the instrument. When the original calibration is done at a location far from the conductor, the indication of the presence of the energized electric conductor is given over a large area. By recalibrating successively closer, the indicated area decreases until the electric energized conductor is closely located.

FIG. 7 shows in a flowchart a process carried out by the above-described AC measurement system 100. The process starts in step 700 when a user turns on the instrument or presses a reset button. The process starts a calibration process in the microprocessor by first determining a background electric field level at the starting location (step 702). This background electric field level is then used as a reference value for the measured electric field from other locations.

The user moves the instrument over an area, such as a wall, to locate a concealed electric energized conductor. The electric field strength is measured at a new location (step 704). The ratio between the background signal level and the electric field strength measured at the new location is calculated (step 706). Ratios is calculated (rather than only subtraction) for the comparison because detection requires the measurement of a small change in electric field level as compared to a large background signal. The actual change in electric field level for a given movement toward or away from the concealed electric conductor is proportional to the level of the background field. Therefore, a ratio gives a constant sensitivity. That is, the change in ratio for a given movement of the sensor is constant. If a difference measurement other than a ratio is used, the sensitivity of the unit would depend on the magnitude of the background signal.

Next, the process determines whether the ratio is less than an empirically predetermined value, e.g., approximately 0.8 (step 708). If the process determines that the ratio is less than or equal to the predetermined value, the instrument is automatically recalibrated (step 710). A new reference level, i.e., a new background signal level, is generated in this step. The process returns to step 704 and continues.

If the process determines that the ratio is not less than the predetermined value, the process determines whether the ratio is greater than a predetermined value, e.g., 1.2 (step 714). Number 1.2 is selected because the optimal ratio is approximately 1.18 (i.e., 18% increase) which is an empirically determined number. If the number is too low, random variations due to wall conditions, such as a stud or nail, can cause erroneous indications. On the other hand, if the number is too high, the instrument may fail to find the hidden conductor. If the ratio is greater than the predetermined value, the process generates a signal indicating that a concealed conductor is present (step 716). The signal generated is, for example, a visual or an audible indication. The process returns to step 704 and continually repeats steps 704 through 716 until the instrument is turned off or a reset switch is activated.

In one embodiment, a single LED having multifunction modes (on, off, or blinking) provides an alert to the presence of an AC signal. For example, a constant on LED indicates the location of a concealed conductor; the off LED indicates the absence of the concealed conductor; and an LED blinking at a constant rate indicates the instrument was calibrated near a the conductor. In one embodiment, the LED blinks at varying rate to indicate whether the instrument is getting closer or farther away from the conductor. For example, an increasing rate indicates that the conductor is getting closer and a decreasing rate indicates that it is getting farther away. Similarly, an audible indicator can be used to indicate the location and the presence or absence of the concealed energized electric conductor with sounds of varying frequencies.

Although the invention has been described with reference to particular embodiments, this description is illustrative and not limiting. Various other adaptations and combinations of features of the embodiments disclosed are within the scope of the invention as defined by the following claims.

We claim:

1. A method for locating an energized electric conductor, comprising the acts of:
calibrating at an initial position relative to the conductor by:
measuring a first signal level at said initial position; and
setting a background signal level to said first signal level;
measuring a second signal level at a second position relative to said conductor;
comparing said second signal level with said background signal level; and
generating a signal indicating a presence of said conductor in response to a result of said comparing.

2. The method of claim 1, wherein said comparing comprises the acts of:
subtracting said background signal level from said second signal level; and
dividing the resulting subtrahend by said background signal level.

3. The method of claim 2, further comprising the act of recalibrating when a resulting dividend is less than said predetermined value.

4. The method of claim 3, wherein said recalibrating comprises the act of setting said background signal level to said second signal level.

5. The method of claim 1, wherein said measuring comprises the acts of:
detecting an electric field signal;
amplifying said detected electric field signal; and
measuring an amplitude of said amplified detected electric field signal.

6. The method of claim 5, wherein said amplifying comprises the acts of:
providing a fixed gain amplifier; and
switching a resistance switch array coupled to said fixed gain amplifier.

7. The method of claim 6, further comprising the act of controlling said switching.

8. The method of claim 5, wherein said measuring further comprises the act of detecting a peak amplitude of said detected electric field signal.

9. The method of claim 8, wherein said detecting a peak amplitude comprises the acts of:
comparing said amplified detected electric field signal with a threshold value;
setting a flip-flop using a result of said comparing, said flip-flop generating an output signal;
resetting said flip-flop using a reset signal; and
generating said threshold value.

10. The method of claim 8, wherein said detecting comprises the acts of:
comparing said amplified detected electric field signal with a threshold value;
generating a control signal for a digital to analog conversion; and
generating said threshold value from said digital to analog conversion.

11. An apparatus for sensing an alternating electric field in a conductor, comprising:
a sensor adapted to be positioned near said conductor;
a programmable gain amplifier coupled to receive signals from said sensor;
an amplitude comparison element coupled to receive signals from said programmable gain amplifier; and
a controller coupled to transmit control signals to said amplitude comparison element, said control signals controlling a reference amplitude of said amplitude comparison element and a gain of said programmable gain amplifier.

12. The apparatus of claim 11, wherein said sensor is an electric field sensor.

13. The apparatus of claim 11, further comprising a case housing said apparatus, said case comprising at least one raised portion on an inside thereof, said sensor being formed on said inside and over said at least one raised portion.

14. The apparatus of claim 13, wherein said sensor is a conductive trace, said apparatus further comprising a substrate on which said programmable gain amplifier, said amplitude comparison element, and said controller are mounted, wherein said trace is in electrical contact with said programmable gain amplifier.

15. The apparatus of claim 11, wherein said programmable gain amplifier comprises:
a switched resistor array coupled to said sensor; and
a fixed gain amplifier having an input terminal coupled to said switched resistor array.

16. The apparatus of claim 15, wherein said switched resistor array comprises a plurality of resistors coupled in series.

17. The apparatus of claim 16, wherein said switched resistor array further comprises a programmable array of switches coupled to said resistors.

18. The apparatus of claim 17, wherein each switch in said programmable array of switches is coupled in series with a corresponding one of said resistors.

19. The apparatus of claim 17, wherein said programmable array of switches is coupled to said controller.

20. The apparatus of claim 15, wherein said switched resistor array comprises a plurality of resistors coupled in parallel.

21. The apparatus of claim 20, wherein said switched resistor array further comprises a programmable array of switches coupled to said resistors.

22. The apparatus of claim 21, wherein each switch in said programmable array of switches is coupled in parallel with a corresponding one of said resistors.

23. The apparatus of claim 22, wherein said programmable array of switches is coupled to said controller.

24. The apparatus of claim 11, wherein said amplitude comparison element comprises:
a comparator having a first input terminal coupled to said programmable gain amplifier, a second input terminal, and an output terminal;
a flip-flop coupled to said output terminal of said comparator and said controller; and
a pulse-width modulator coupled to said controller and said second input terminal of said comparator.

25. The apparatus of claim 24, wherein said flip-flop stores state changes of said comparator.

26. The apparatus of claim 11, wherein said amplitude comparison element comprises:
a comparator having a first input terminal coupled to said programmable gain amplifier, a second input terminal, and an output terminal coupled to said controller; and
a digital-to-analog converter coupled to said controller and said second input terminal of said comparator.

27. The apparatus of claim 11, further comprising an indicator coupled to said controller.

28. The apparatus of claim 27, wherein said indicator is selected from a group consisting of a visual display and an audible indicator.

29. The apparatus of claim 28, wherein said visual display is an LED.

30. The apparatus of claim 29, wherein said LED is a multifunction mode LED.

31. A method for making a conductive sensor, comprising:
providing a case having at least one raised portion on an inside portion of said case;
mounting a printed circuit board in said case; and
printing a conductive region on said inside portion over said raised portion, whereby said conductive region is in electrical contact with associated circuitry on said printed circuit board.

32. An apparatus for sensing an electric field comprising:
a case having at least one raised portion on an inside thereof;
a printed circuit board mounted in said case, signal processing circuitry being mounted on said printed circuit board; and
an electrically conductive sensor formed on said raised portion and electrically contacting said printed circuit board.

33. The apparatus of claim 32, wherein said electrically conductive sensor is of conductive ink.
